(19) United States
(12) Patent Application Publication
(10) Pub. No.: US 2013/0221378 A1
(43) Pub. Date: Aug. 29, 2013

(54) LIGHT EMITTING DIODE AND METHOD FOR MANUFACTURING THE SAME

(71) Applicants: Tokuhiko MATSUNAGA, Fukuoka-ken (JP); Katsufumi Kondo, Fukuoka-ken (JP)

(72) Inventors: Tokuhiko MATSUNAGA, Fukuoka-ken (JP); Katsufumi Kondo, Fukuoka-ken (JP)

(73) Assignee: KABUSHIKI KAISHA TOSHIBA, Tokyo (JP)

(21) Appl. No.: 13/605,899

(22) Filed: Sep. 6, 2012

(30) Foreign Application Priority Data
Feb. 28, 2012 (JP) P2012-042279

(51) Int. Cl. H01L 33/62

(52) U.S. Cl. 257/79; 438/22; 257/E33.066

(57) ABSTRACT

An LED manufacturing method includes the steps of forming a first insulator film on a semiconductor layer, forming a laminated body including a mask layer and an electrode on the first insulator film, forming a second insulator film to cover the laminated body and a first region of the first insulator film where a laminated body is not formed, anisotropic etching the second insulator film to expose the top surface of the mask layer and a second region of the first insulator film, exposing the surface of a semiconductor layer by removing the first insulator film while keeping the first insulator film between the laminated body and the semiconductor layer, removing the mask layer, and forming a clear conducting layer on top of the exposed surface of the semiconductor layer and the electrode.

### CROSS-REFERENCE TO RELATED APPLICATION

This application is based upon and claims the benefit of priority from Japanese Patent Application No. 2012-042279, filed Feb. 28, 2012; the entire contents of which are incorporated herein by reference.

### FIELD

Embodiments described herein relate to a light emitting diode (LED) and its manufacturing method.

### BACKGROUND

In the case in which the upper surface of an LED is the light extraction surface, if the electrode (through which current will be injected) is configured to have a thin and long shape, then shading by the luminous layer will be reduced to increase brightness.

For example, if a contact layer is the ground layer of the thin electrode then forward voltage will be reduced. In the case in which a thin electrode is patterned onto the top of the contact layer, taking into account mask alignment error, the contact layer width will be greater than the electrode width. In this case, a contact layer that contains a high impurity concentration will have high light absorption for certain wavelengths. The contact layer material will work as an absorption layer, thus reducing brightness.

Conversely, when a thin electrode is used as an etching mask, the etching leaves behind only a lower contact layer—all of which, or nearly all of which, is in contact with the electrode. By over-etching, however, the width of the contact layer becomes less than the width of the electrode. From this result, an increase in forward voltage or electrode separation is more likely to occur, leading to difficulty in maintaining stable production. This disclosure describes techniques which provide for the removal of parts of the contact region that otherwise would reduce brightness. These techniques also mitigate the problems associated with over-etching.

### DESCRIPTION OF THE DRAWINGS

FIG. 1A is a schematic plan view of the LED relating to the first embodiment; FIG. 1B is a schematic cross-sectional view along the A-A line; FIG. 1C is a partially enlarged schematic cross-sectional view of the NW region.

FIG. 2 is a schematic cross-sectional view of the near field region of the thin wire unit of an LED according to a comparative example.

FIGS. 3A to 3E are the schema explaining the manufacturing method of an LED according to a first embodiment.

FIG. 4 is a schematic cross-sectional view of an alternative electrode structure.

FIG. 5 is a graph representing the dependence of the side wall width to the insulator film thickness.

FIG. 6A is a schematic plan view of an LED according to a second embodiment; FIG. 6B is a schematic cross-sectional view along the A-A line; FIG. 6C is a partially enlarged schematic cross-sectional view of the NW region.

FIGS. 7A to 7E are the schema explaining the manufacturing method of the LED of the second embodiment.

FIGS. 8A to 8C are the schema explaining the manufacturing method of an LED according to an alternative to the second embodiment.

FIG. 9A is a schematic plan view of the LED of the alternative to the second embodiment; FIG. 9B is a schematic cross-sectional view along the A-A line; FIG. 9C is a partially enlarged schematic cross-sectional view of the NW region.

### DETAILED DESCRIPTION

In general, for each embodiment, refer to the drawings provided to further explain the mode for carrying out the invention.

According to a first embodiment, there is provided an LED—and its manufacturing method—that can easily and stably increase its brightness while maintaining low forward voltage.

The manufacturing method for the LED of the first embodiment includes a process to form a first insulator film on a surface of a semiconductor layer, a process to form a laminated body containing a first electrode and mask layer, a process to form a second insulator film, a process to anisotropically etch the second insulator film, a process to expose the semiconductor surface, a process to eliminate the mask layer, and a process to form a clear conducting layer. The process to form a laminated body includes a process of forming a bonding pad unit provided on a first surface of the first insulator film, forming a first electrode having a thin wire unit projecting from the bonding pad unit, and forming a mask layer provided on top of the first electrode. The process of forming the insulator film includes the process of forming the second insulator film covering the laminated body and the first region, the region within the first surface that does not form the laminated body.

The process of anisotropic etching includes the process of etching the second insulator film by leaving a portion of the second insulator film as a lateral insulator film by covering two lateral surfaces of the thin wire unit while exposing the mask layer and the second region, which is the region within the first surface that does not form the thin wire unit and lateral insulator film. The process of exposing the surface of the semiconductor layer includes the process of leaving the region within the first insulator film (in which the thin wire unit and lateral insulator film are arranged into a predetermined position) as the ground layer while eliminating the second region of the first insulator film to expose the surface of the semiconductor layer. The process of eliminating the mask layer includes the process of eliminating the mask layer above the first electrode. The process of forming the clear conducting layer includes the process of forming the clear conducting layer by covering the lateral insulator surface, designated regions of both sides of the ground layer of the exposed surface of the semiconductor layer, and the surface of the thin wire unit.

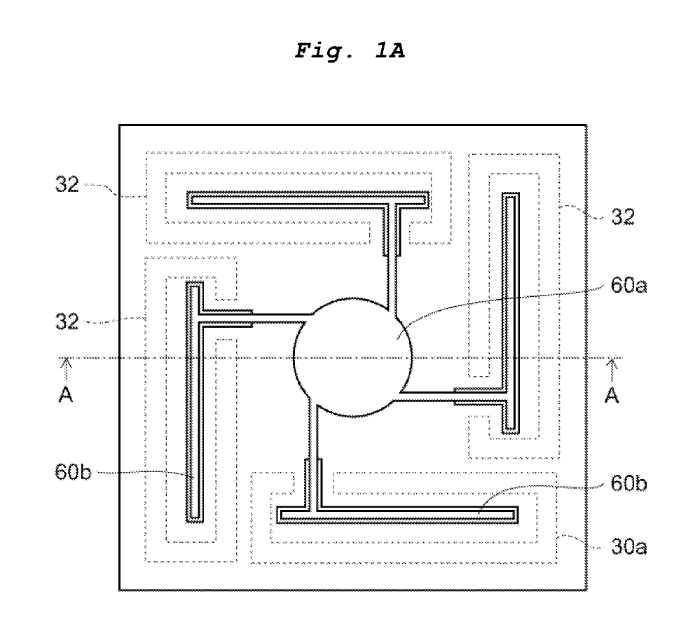

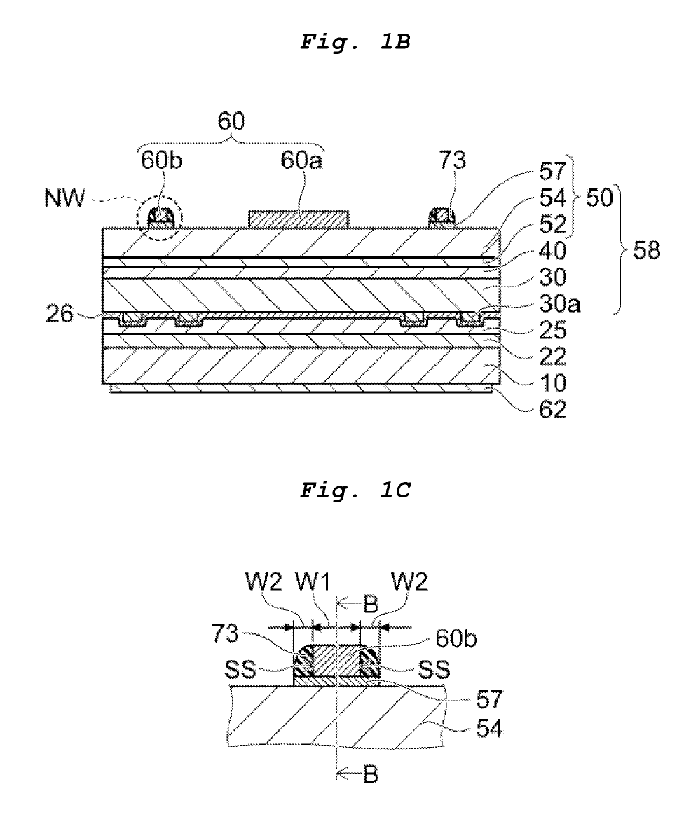

FIG. 1A is a schematic plan view of the LED relating to the first embodiment; FIG. 1B is a schematic cross-sectional view along the A-A line; FIG. 1C is a partially enlarged schematic cross-sectional view of the NW region. The LED includes a semiconductor layer 58, a first electrode 60, and lateral insulator film 73.

Semiconductor layer 58 includes luminous layer 40, first conductivity type, layer 30, and second conductivity type layer 50. Second conductivity type layer 50 is set in between luminous layer 40 and first electrode 60. Additionally, first conductivity type layer 30 is set on a side of luminous layer 40 which is opposite the side on which second conductivity type layer 50 is set.

First electrode 60, which includes bonding pad unit 60a and thin wire unit 60b (which is projected outward from bonding pad 60a), is set on top of second conductivity type layer 50. Additionally, lateral insulator film 73 is disposed on two lateral surfaces of thin wire unit 60b. The lateral insulator film 73 is configured to be permeable to light emitted from luminous layer 40.

First conductivity type layer 30 may include, for example, a clad layer, a current diffusion layer, and a first contact layer 30a, in this order. Second conductivity type layer 50 may include a clad layer 52, a current diffusion layer 54, and a ground layer 57 disposed in the order recited, starting on the luminous layer 40 side.

Clear conducting layer 26 may be set on the bottom surface of first conductivity type layer 30, and reflective metal layer 25 may be disposed below the clear conducting layer 26. The semiconductor layer 58 wafer, which is composed of material such as Si, is bonded to supporting basal plate 10 through metal junction layer 22. Additionally, on the opposite side of the supporting basal plate 10, back electrode 62 is set.

In FIG. 1C, thin wire unit 60b is set on top of ground layer 57, which acts as a second contact layer. Lateral insulator film ‘73, which covers two lateral surfaces SS of thin wire unit 60b, is also set on top of ground layer 57. Lateral insulator film 73 may be made, for instance, of SiO₂, Si₃N₄, or SiON. The lateral insulator film 73 may be configured so that light emitted from luminous layer 40 can permeate the insulator film.

In terms of current-feed, it is favorable to set the conductivity type of ground layer 57 to the same conductivity type as the surface layer of semiconductor layer 58. That is, in the example from FIGS. 1A to 1C, it is good to have the conductivity type of the ground layer 57 the same as that of the second conductivity type layer 50. Additionally, if the impurity concentration of ground layer 57 is set higher than the impurity concentration of current diffusion layer 54 (which is a part of the second conductivity type layer 50), then contact resistance within thin wire unit 60b can be reduced.

In this embodiment, ground layer 57 is formed using a self-alignment process, thus it is almost symmetrical on both sides of line B-B, which is a centerline through thin wire unit 60b. Additionally, the amount of sideward extension of the ground layer 57 from each of two lateral surfaces SS of thin wire unit 60b can be substantially equivalent, and can be an extension of less than 1 μm. With ground layer 57 being symmetrical on both sides of centerline B-B through thin wire unit 60b, the left and right conductive layers of ground layer 57 provide uniform resin coverage, leading to improvement in device characteristics and reliability.

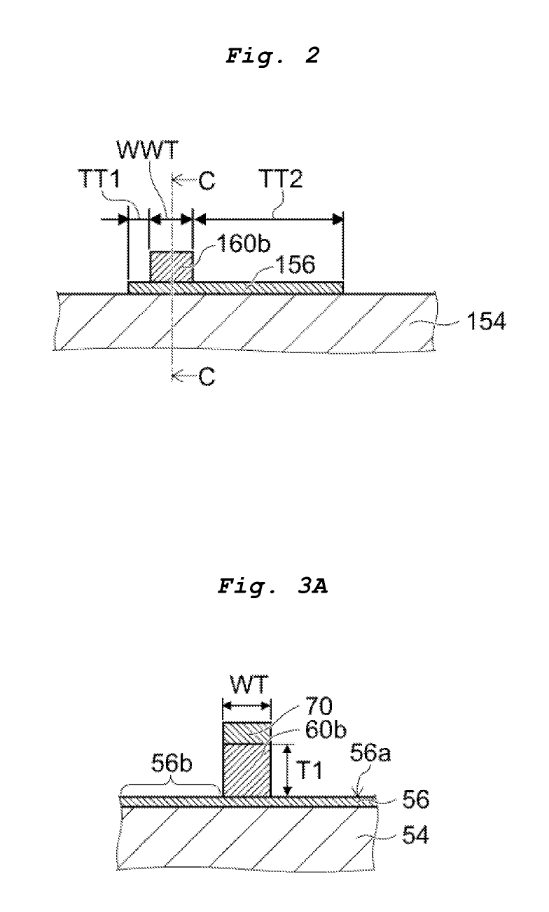

FIG. 2 is a schematic cross-sectional view of the near field region of the thin wire unit in an LED of the comparative example. For the comparative example in which the self-alignment process is not used, though the thin wire unit 160b width WWT is approximately 3 μm, second contact layer 156 width (TT1+WWT+TT2) is as much as 6 to 10 μm. At the same time, second contact layer 156 is likely asymmetrical along centerline C-C through thin wire unit 160b. This asymmetry is due to the mask alignment error being large. Additionally, in the comparative example, second contact layer 156, which contains a high impurity concentration, is wide. This disposition causes high light absorption, which is more likely to reduce brightness than the device disclosed herein.

In this embodiment, as a response, there can be a reduction of the lateral extension of ground layer 57 in the sideward direction beyond lateral surface SS of thin wire unit 60. This reduction leads to reducing unnecessary light absorption by ground layer 57. Because of this, light extraction efficiency can be increased to about 120% of the efficiency of the LED in the comparative example. Also, according to an experiment by the inventors, decreasing the amount of projection did not cause an increase in forward voltage V_{F}.

Lateral insulator film 73 acts as a protection layer as well. An example of this effect occurs when thin wire unit 60b contains a barrier metal layer to restrain diffusion of an element such as Ga from semiconductor layer 58 to thin wire unit 60b. In this case, the barrier metal layer may peel off due to, say, corrosion. Lateral insulator film 73 acts as a protective layer against such corrosion.

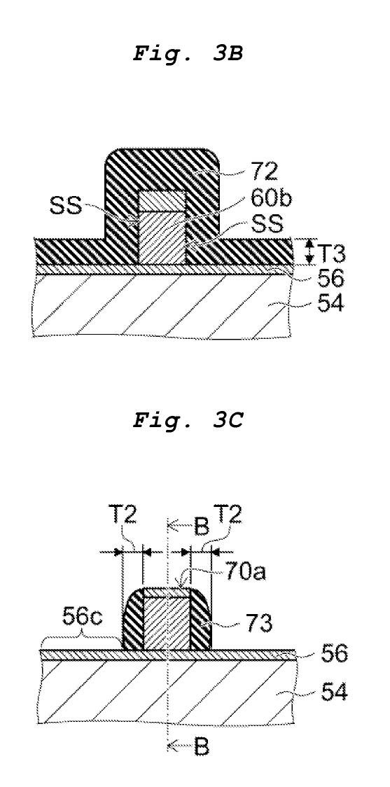

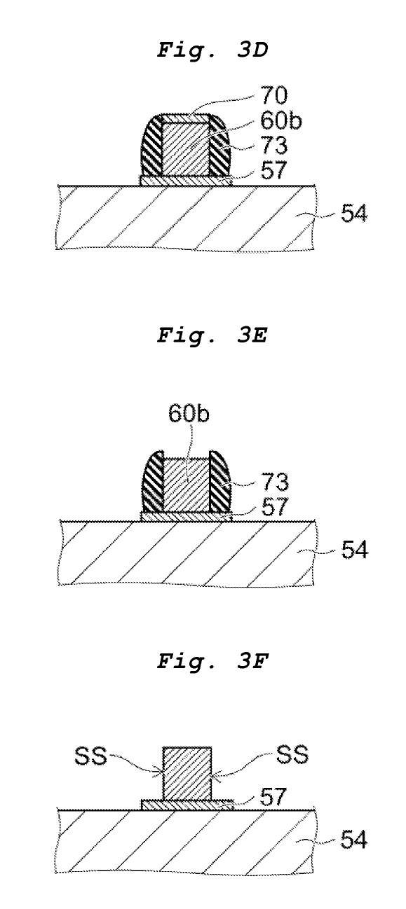

FIGS. 3A to 3F are figures explaining the manufacturing method of the LED of the first embodiment. FIG. 3A is a cross-sectional view of the thin wire unit formed by lift-off technology. FIG. 3B is a cross-sectional view of the NW region that forms the insulator film. FIG. 3C is a cross-sectional view of the NW region on which the insulator film is etched. FIG. 3D is a cross-sectional view of the NW region that forms the ground layer through patterning. FIG. 3E is a cross-sectional view after the mask layer has been removed. FIG. 3F is a cross-sectional view after the lateral insulator film has been removed.

In FIGS. 3A to 3F, the LED is represented as composition formula In (Ga_{y}Al_{1-y}) ₁₋ₓP (where 0≦x≦1, 0≦y≦1) in which InGaAlP based materials are included. AlGaAs based materials represented by the composition formula AlₓGa₁₋ₓAs (0≦x≦1) or InGaAlN based materials represented by the composition formula InₓGa_{y}Al_{1-x-y}N (0≦x≦1, 0≦y≦1, x+y≦1) are also acceptable.

In semiconductor layer 58, second conductivity type layer 50 is on top of luminous layer 40. Second conductivity type layer 50 is n-type, and includes clad layer 52, current diffusion layer 54, and second contact layer 56. Clad layer 52 is covered by current diffusion layer 54. Current diffusion layer 54 is composed of InGaAlP based material, and, in turn, is covered by second contact layer 56, which is composed of GaAs. In addition, first conductivity type layer 30 contains first contact layer 30a on its side which faces the metal junction layer 22.

A photo resist pattern is formed on a first surface 56a of second contact layer 56. On first surface 56a, a first metal layer composed of material such as AuGe/Au and a film composed of material such as Ti may be formed. The formation may involve a method such as the evaporation method. By lift-off technology, first electrode 60 composed of AuGe/Au and mask layer 70 composed of Ti set above forms a laminated body.

FIG. 3A shows the NW region represented in FIG. 1B of first electrode 60. Thin wire unit 60b and, above it, mask layer 70 WT, have a width that is preferably 2 to 10 μm, and even more preferably, 3 to 6 μm. Thin wire unit 60b has a height T1 that is preferably 0.1 to 1 μm, and even more preferably 0.2 to 0.4 μm. In addition, after forming a first metal layer composed of material such as AuGe/Au and a film composed of material such as Ti using a method such as the evaporation method, photo resist may be used for patterning.

As shown in FIG. 3B, a normal pressure CVD (Chemical Vapor Deposition) method is used to form insulator film 72, which is composed of material such as SiO₂, Si₃N₄, or SiON, and which is formed to cover first region 56b of first surface 56a and thin wire unit 60b. The thickness of insulator film 72 is depicted as T2 and may be, for instance, 0.1 to 2 μm.

As shown in FIG. 3C, anisotropic etching is applied to etch insulator film 72 until the point at which second region 56c of first surface 56a of second contact layer 56 and top surface 70a of mask layer 70 are exposed. In this case, when an anisotropic etching method such that the cross-direction etching rate is less than the depth direction etching rate is applied, an insulator film configuration such as the one depicted in the cross-sectional view of FIG. 3C is created. Additionally, as a method for anisotropic etching, a dry etching method including plasma etching or RIE (Reactive Ion Etching) can be applied. As a result of the etching, lateral insulator film 73 is formed through self-alignment to be substantially symmetrical along both sides of central line B-B of thin wire unit 60. Additionally, due to applying the self-alignment process, lateral insulator film 73 can be formed with good dimensional control down to submicron levels, which is advantageous for device stability.

As shown in FIG. 3D, solution etching is used to remove second region 56c of second contact layer 56. The etching solution may be, for instance, a phosphoric acid and hydrogen peroxide solution or a sulfuric acid and hydrogen peroxide solution. Following solution etching, ground layer 57 which is symmetrical about centerline B-B through thin wire unit 60b will remain. Even if thin wire unit 60b were to be patterned based on the centerline of patterned ground layer 57, it would be very difficult to maintain such high levels of symmetry as when the self-alignment process is used.

As shown in FIG. 3E, mask layer 70 is removed. As shown in the FIG. 1C embodiment, the lateral insulator film 73 may be left, and this lateral insulator film acts as a protection film. However, for the case in which the lateral insulator film is removed, FIG. 3F is a cross-sectional view showing the further removal of lateral insulator film 73.

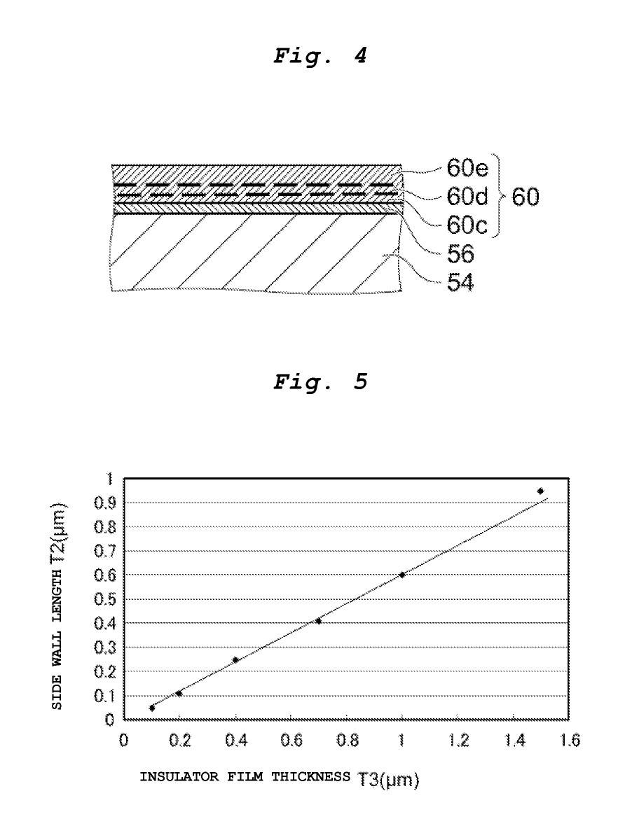

FIG. 4 is a schematic cross-sectional view showing an alternative to the first electrode 60 structure. AuGe film 60c, Mo film 60d, and Au film 60e are set on top of Second contact layer 56 in this order. Setting Mo as a barrier metal in between AuGe and Au restrains diffusion of Ga within semiconductor layer 58. Mo is easily decayed and thin wire unit 60b may peel off, leading to a decline in reliability of the component. However, leaving lateral insulator film 73 will restrain the decay in the barrier metals, leading to increase in reliability.

If packaging with improved airtight characteristics is used, lateral insulator film 73 may be removed like in FIG. 3F. By doing this, a portion of ground layer 57 extends sideward beyond two lateral surfaces SS of thin wire unit 60b. Removal of the insulating film renders these extending portions of ground layer 57 wider by a distance of T2 in each direction, where T2 is the width of each insulating film sidewall. Furthermore, side wall width T2 is slightly less than the width of the portions of the second contact layer 56 which extend sideward from thin wire unit 60b after the lateral insulator film 73 is removed.

FIG. 5 is a graph representing the dependence of the side wall width on the thickness of insulator film prior to etching. The vertical axis is the side wall width T2 (μm) of insulator film 73. The horizontal axis is the insulator film 72 thickness T3 (μm) prior to etching. Additionally, first electrode 60 thickness is 0.3 μm, and thin wire unit 60b width is 3 μm. The plasma etching method is applied as the dry etching method.

When insulator film 72 thickness T3 is 0.1 μm prior to etching, side wall width T2 will be small, roughly 0.05 μm. As insulator film 72 thickness T3 increases, side wall width T2 increases. For example, when insulator film 72 thickness T3 is 1.5 μm, side wall width T2 is 0.94 μm.

For this embodiment, it is preferred that insulator film 72 thickness prior to etching T3 be in the range of 0.1 to 1.5 μm. Additionally, it is even more preferable for insulator film 72 thickness T3 to be in the range of 0.12 to 1 μm, so as to keep side wall width T2 as small as 0.06 to 0.6 μm, thereby maintaining the effectiveness of the protection layer. Furthermore, using this range, it is easier to reduce light absorption by the contact layer than it is in the comparative example (FIG. 2), in which the projection TT1 and TT2 is large.

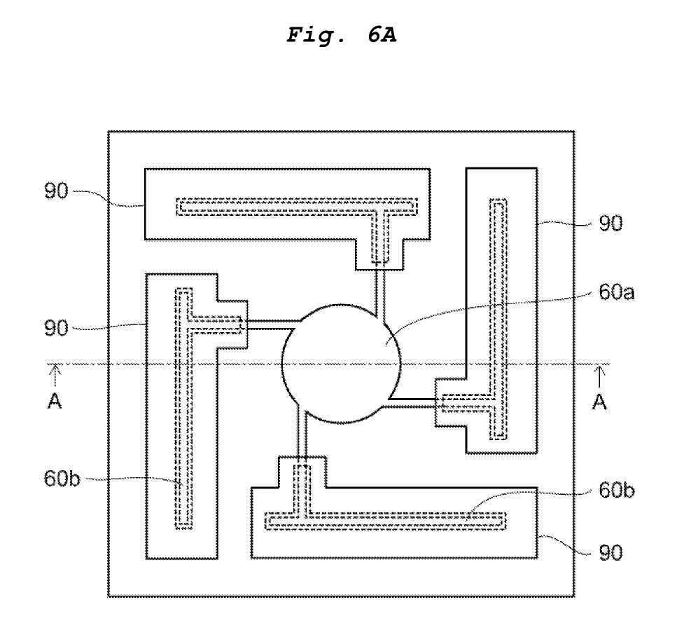

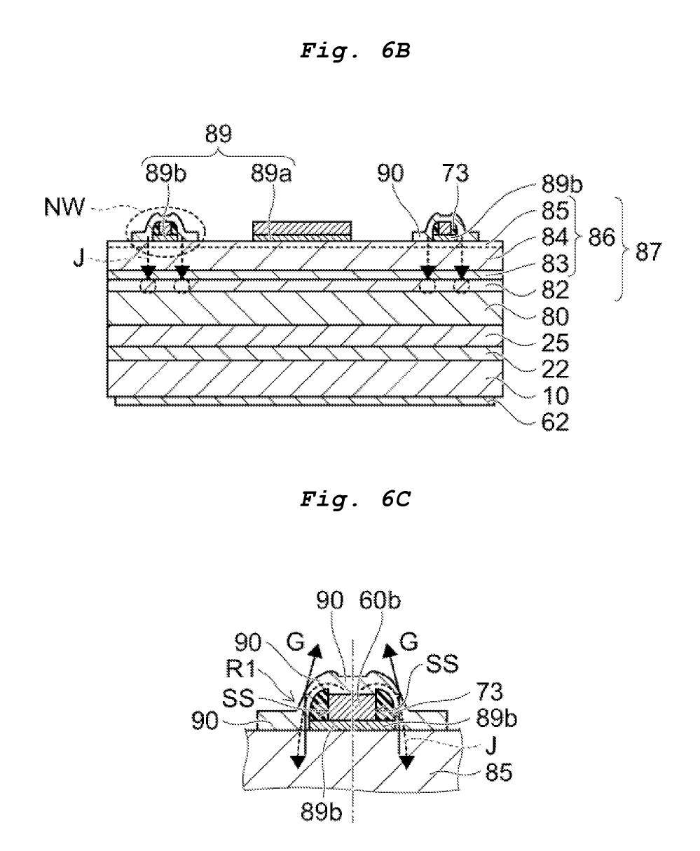

FIG. 6A is a schematic plan view of an LED of the second embodiment. FIG. 6B is a schematic cross-sectional view along the A-A line; FIG. 6C is a partially enlarged schematic cross-sectional view of the NW region that is in the neighborhood of the thin wire unit. The LED includes lateral insulator film 73 (composed of material having the same conductivity type as semiconductor layer 87, ground layer 89, first electrode 60, and second insulator film) and clear conducting layer 90.

Semiconductor layer 87 may be made of InGaAlN based material, InGaAlP based material, or AlGaAs based material. Semiconductor layer 87 includes luminous layer 82, first conductivity type layer 80, and second conductivity type layer 86. Second conductivity type layer 86 is set between luminous layer 82 and first electrode 60. Additionally, first conductivity type layer 80 is set on the same side of luminous layer 82, opposite where second conductivity type layer 86 is set.

As shown in FIG. 6A and FIG. 6B, first electrode 60, including bonding pad unit 60a and thin wire unit 60b (which is displaced from bonding pad 60a) is set on top of a GaN layer that forms the surface of second conductivity type layer 86. Additionally, lateral insulator film 73 is formed on two lateral surfaces SS of thin wire unit 60b, and is permeable to light emitted from luminous layer 82.

Semiconductor layer 87 wafer is bonded to supporting basal plate 10 through metal junction layer 22. On the back side of the supporting basal plate 10, back electrode 62 is fixed.

First electrode 60 is set on top of ground layer 89, which is composed of insulator film. Clear conducting layer 90 is set in a way that covers the upper portion of the near field NW region of thin wire unit 60b and the upper surface of semiconductor layer 87. By configuring the conducting layer in this manner, current J (represented by a dotted line) can be injected into semiconductor layer 87 within the NW region byway of clear conducting layer 90. Because of this current, light is emitted from luminous layer 82 at a locating below thin wire unit 60b. In this case, lateral insulator film 73 and clear conducting layer 90 form a convex shape that extends upwards, but which may also have a flattened cavity part positioned slightly below the uppermost point of the lateral insulator film 73.

If either the clear conducting layer 90 or lateral insulator film 73 has a refractive index greater than the refractive index of the sealing resin layer, emitted light G from luminous layer 82 can be easily concentrated at the upper portion of thin wire unit 60b. Additionally, clear conducting layer 90 has curved sides R1 at positions above the left and right corner sections where the layer begins to turn upwards. Because of this configuration, adhesion is improved between the sealing resins.

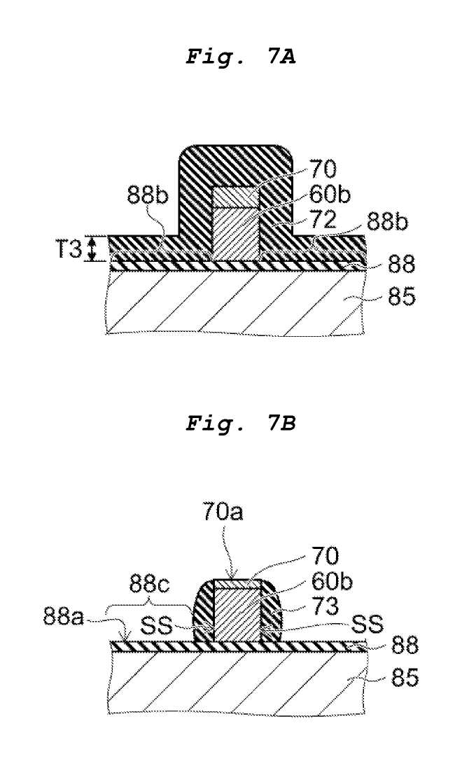

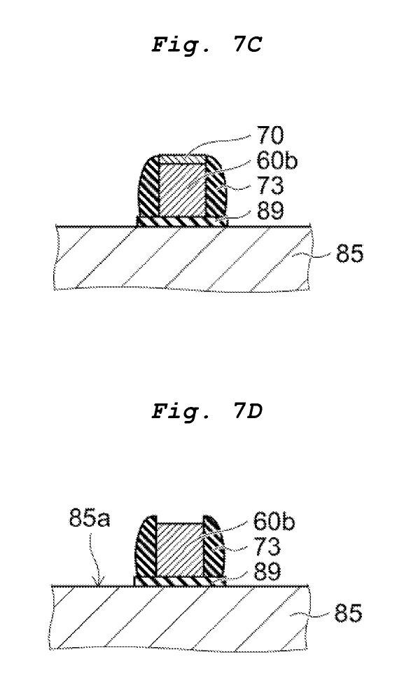

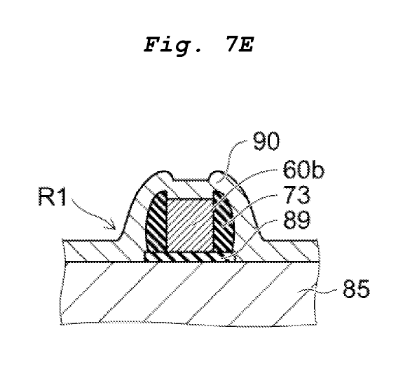

FIGS. 7A to 7E are figures explaining the manufacturing method of the LED of the second embodiment. FIG. 7A is a cross-sectional view of the NW region during the manufacturing process when covered by the insulator film. FIG. 7B is a cross-sectional view of the NW region when the second insulator film is etched. FIG. 7C is a cross-sectional view of the NW region when the ground layer is patterned. FIG. 7D is a cross-sectional view of the NW region after the mask layer has been removed. FIG. 7E is a cross-sectional view of the NW region after the clear conducting layer has been formed.

In FIGS. 7A to 7E, semiconductor layer 87 includes InGaAlN based materials. As previously depicted, in semiconductor layer 87, second conductivity type layer 86 is formed on top of luminous layer 82. second conductivity type layer 86 is n-type, and also includes current diffusion layer 84, which is composed of InGaAlN, as well as a second contact layer 85 composed of GaN formed on the current diffusion layer 84.

In FIG. 7A, using a method such as lift-off technology, a laminated body is formed on first surface 88a of first insulator film (first film) 88. The laminated body consists of a thin wire unit 60b (composed of material such as Ni/Au) and a mask layer 70 formed thereon. A second insulator film 72 is formed to cover the laminated body and a first region 88b of first surface 88a (first region 88b is discontinuous and exists on two sides of thin wire unit 60b). The first region 88b consists of the parts of the first surface 88a on which a laminated body is not formed. The second insulator film 72 is composed of a material such as Si₃N₄, SiON, or SiO₂, and is formed using a method such as the CVD method. The thickness T3 of first insulator film 88 can be, for instance, 0.1 to 2 μm.

As shown in FIG. 7B, anisotropic etching is applied to etch the second insulator film 72 until the first surface 88a of the first insulator film 88 and top surface 70a of mask layer 70 is exposed.

As shown in FIG. 7C, ground layer 89 is formed by removal of second region 88c of first insulator film 88 using the self-alignment method.

When etching the second insulator film 72, insulator film 88 is etched away at the second region 88c. The result is that ground layer 89 remains, in a position such that on top of ground layer 89, thin wire unit 60b and lateral insulation film 73 form a laminated structure. This is how surfaces 85a of first contact layer 85 are exposed. Also, when the first insulation film 88 and second insulation film 72 are formed of Si₃N₄, the etching solution can be a hydrofluoric acid based chemical.

As shown in FIG. 7D, mask layer 70 is removed, exposing thin wire unit 60b. During this process, if the surface of bonding pad unit 60a is exposed, then wire bonding is simple.

Clear conducting layer 90 is formed so as to cover the surface of lateral insulation film 73, the exposed surface 85a of second contact layer 85, and thin wire unit 60b. Using ITO (Indium tin oxide) or tin oxide to form clear conducting layer 90 makes it difficult to form an alloy layer when the second contact layer 85 is composed of GaN. Because of this, light absorption is restrained while keeping forward voltage V_{F} low.

Additionally, if ground layer 89 isn't patterned in a self-aligned manner, the distance between the upper surface of thin wire unit 60b and surfaces 85a of second contact layer 85 will be longer than when self-alignment is used, thereby leading to an increase in voltage drop caused by clear conducting layer 90, and an increase in forward voltage V_{F}. Because of this, ohmic loss will increase.

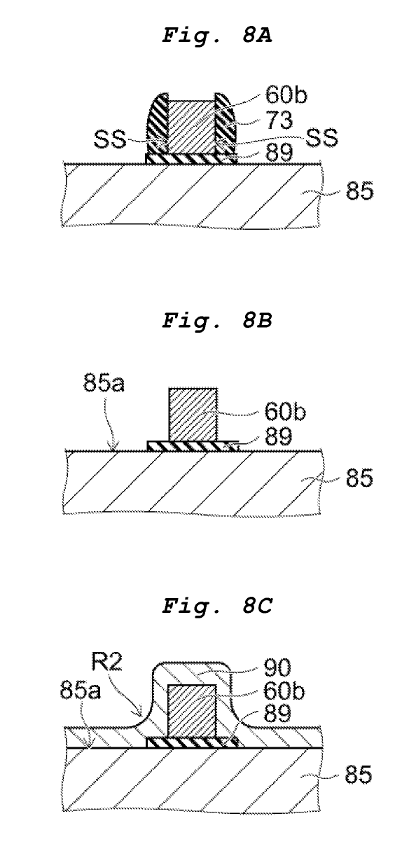

FIGS. 8A to 8C are diagrams explaining the manufacturing method of an alternative LED of the second embodiment.

Here, the lateral insulation film 73 is removed from the two lateral surfaces SS of thin wire unit 60b, as depicted in FIG. 8B. Additionally, clear conducting layer 90 is formed to cover surfaces 85a of second contact layer 85 and the surface of thin wire unit 60b. The corner section R2 of clear conducting layer 90 has roundness that increases adhesion with the sealing resin layer.

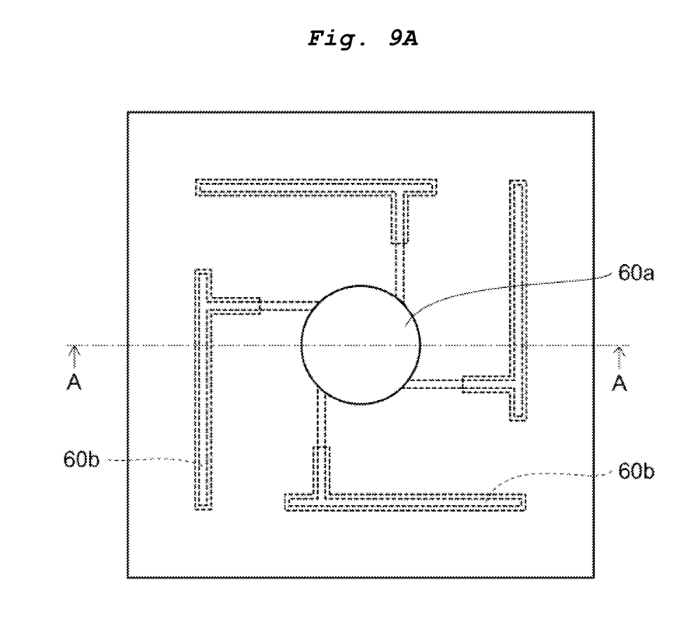

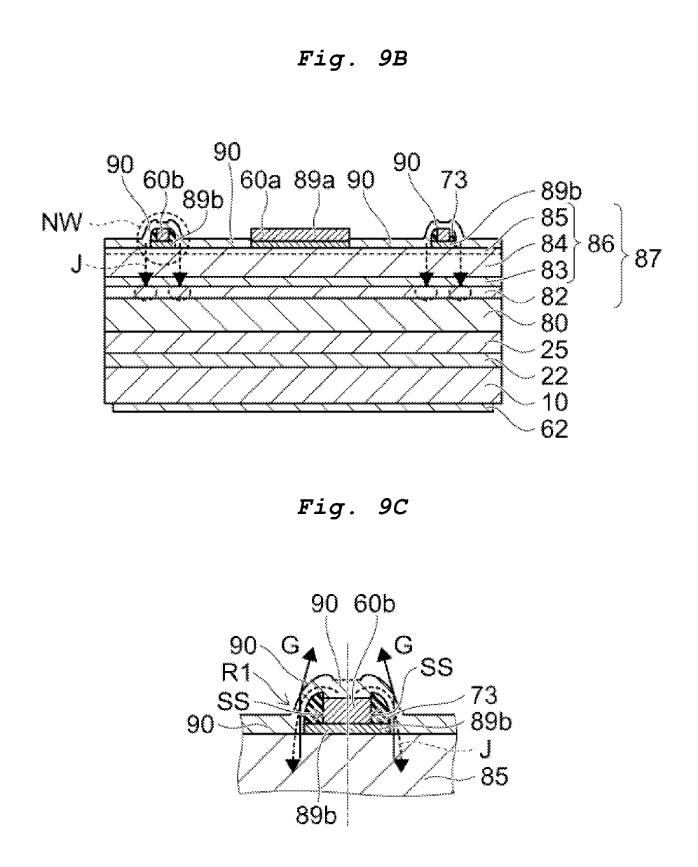

FIG. 9A is a schematic plan view of an additional alternative LED of the second embodiment; FIG. 9B is a schematic cross-sectional view of this additional alternative LED at the A-A line; FIG. 9C is a partially enlarged schematic cross-sectional view of the NW region of the additional alternative LED. Clear conducting layer 90 may be disposed to cover the surface of the chip of the surface of bonding pad unit 60a, eliminating the region where wire bonding will occur.

For the first and second embodiment and the accompanying modification of the LED, the thin wire unit where the current is injected is arranged above the self-aligned ground layer 89b. The disposition of these components is such that the ground layer is wider than the thin wire unit, which enables it to be more compact while maintaining the designated width. This increases LED brightness while enabling the LED to maintain low forward voltage. Additionally, due to the self-alignment process, an LED containing a thin wire electrode can be manufactured with high mass productivity.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for manufacturing a light emitting device, the device comprising a semiconductor layer, the semiconductor layer including a luminous layer and an electrode comprising a thin wire unit and a bonding pad unit, the method comprising the steps of:
forming a first insulator film on a surface of the semiconductor layer;
forming the electrode on a first region of a surface of the first insulator film and a mask layer on the first electrode;
forming a second insulator film covering the laminated body and a second region of the surface of the first insulator film, the second region not having the electrode formed thereon;
anisotropically etching the second insulator film to expose a portion of the second region of the first insulator film and a top surface of the mask layer, wherein the second insulator film covers two sides of the electrode after etching;
removing a part of the exposed portion of the second region of the first insulator film to expose a portion of the surface of the semiconductor layer and to form a ground layer which is made of a remaining part of the first insulator film;
removing the mask layer previously formed on the first electrode; and
forming a clear conducting layer that covers the surface of the second insulator film, the exposed semiconductor layer, and the surface of the electrode.

2. The method of claim 2, wherein the clear conducting layer also covers surfaces of the ground layer which are not covered by the second insulator film or the electrode.

3. The method of claim 2, wherein forming the second insulator film comprises forming the second insulator film to have a layer thickness of between 0.1 μm and 2 μm prior to etching.

4. The method of claim 3, wherein the surface of the ground layer not covered by the second insulator film or the electrode has a width of 0.05 μm to 0.94 μm, as measured in a direction parallel to the surface of the semiconductor layer.

5. The method of claim 4, wherein the second insulator film comprises one of SiO₂, Si₃N₄, and SiON.

6. A method for manufacturing a light emitting device, the device comprising a semiconductor layer including a luminous layer, and an electrode comprising a thin wire unit and a bonding pad unit, the method comprising the steps of:
forming a first film on a surface of the semiconductor layer;
forming the electrode on a first region of a surface of the first film;
forming a mask layer on the electrode;
forming an insulator film covering the electrode and a second region of the surface of the first film, the second region not having the laminated body formed thereon;
anisotropically etching the insulator film to expose a portion of the second region of the first film and a top surface of the mask layer;
removing part of the exposed portion of the second region of the first film to form a ground region that includes a portion of the first film between the electrode and the semiconductor layer and to expose a surface of the semiconductor layer; and
removing the mask layer on the electrode.

7. The method of claim 6, wherein the first film is of the same conductivity type as the conductivity type of the surface of the semiconductor layer.

8. The method of claim 7, wherein the conductivity type is n-type.

9. The method according to claim 6, further comprising
forming a clear conductive layer that covers a portion of the surface of the exposed semiconductor layer, and the surface of the electrode.

10. The method of claim 6, wherein the insulator film remains on lateral sides of the electrode after the step of anisotropically etching.

11. The method of claim 10, further comprising removing the insulator film on the lateral sides of the electrode.

12. The method of claim 10, wherein each of first and second portions of the ground region is not covered by the electrode.

13. The method of claim 12, wherein each of the first and second portions of the ground region has a width of 0.05 μm to 0.94 μm, as measured in a direction parallel to the surface of the semiconductor layer.

14. The method of claim 13, wherein each of the first and second portions of the ground region is located outward of opposing sides of the electrode.

15. The method of claim 14, wherein forming the insulator film comprises forming the insulator film so that the film has a layer thickness of between 0.1 μm and 2 μm prior to the step of anisotropically etching.

16. A light emitting device comprising:
a semiconductor layer, the semiconductor layer including a luminous layer;
a ground layer composed of insulator film disposed on a surface of the semiconductor layer;
an electrode disposed on the ground layer, the electrode comprising a bonding pad unit and a thin wire unit protruding from the bonding pad unit; and
a clear conductive layer covering a top surface of the thin wire unit and regions of the ground layer that extend laterally from sides of the electrode.

17. The light emitting device according to claim 16, further comprising:
a lateral insulator film disposed on both an upper surface of the ground layer and side surfaces of the thin wire unit.

18. The light emitting device according to claim 17, wherein the ground layer extends laterally from the lateral insulator film to directly contact the clear conductive layer on an upper surface thereof.

19. The light emitting device according to claim 18, wherein each of first and second portion of the ground region that contact the clear conductive layer on an upper surface thereof has a width of 0.05 μm to 0.94 μm, as measured in a direction parallel to the surface of the semiconductor layer.

20. The light emitting device of claim 19, wherein
the ground layer includes a semiconductor having the same conductivity type as the conductivity type of the surface layer of the semiconductor layer.
